(19) United States
(12) Patent Application Publication
(10) Pub. No.: US 2025/0273285 A1
(43) Pub. Date: Aug. 28, 2025

(54) DEFECT REPAIR CIRCUIT AND MEMORY

(71) Applicant: CXMT Corporation, Hefei City (CN)

(72) Inventors: Xian FAN, Hefei City (CN); JUNGHWA LEE, Hefei City (CN)

(73) Assignee: CXMT Corporation, Hefei City (CN)

(21) Appl. No.: 19/207,276

(22) Filed: May 13, 2025

Related U.S. Application Data
(63) Continuation of application No. PCT/CN2024/085225, filed on Apr. 1, 2024.

(30) Foreign Application Priority Data
Apr. 17, 2023 (CN) 202310426968.X

(51) Int. Cl. G11C 29/00

(52) U.S. Cl. CPC G11C 29/76; G11C 29/789; G11C 29/84

(57) ABSTRACT

A defect repair circuit includes a matching module, a bus, and a transmission processing module. The matching module is connected to the bus and configured to receive a target address and a plurality of defect addresses, match the target address with the plurality of defect addresses respectively to generate a plurality of matching signals, and transmit the matching signals to the bus. The target address is an address to be accessed by the current operation. The transmission processing module is connected to the bus and configured to receive the plurality of matching signals through the bus and generate and output a repair indication signal according to the plurality of matching signals.

### CROSS-REFERENCE TO RELATED APPLICATIONS

This is a continuation application of International Application No. PCT/CN2024/085225 filed on Apr. 1, 2024, which claims priority to Chinese Patent Application No. 202310426968.X filed on Apr. 17, 2023. The disclosures of the above-referenced applications are hereby incorporated by reference in their entirety.

### BACKGROUND

A memory is generally provided with redundant (Redundancy) memory cells. In the case that part of the memory cells of the memory cannot implement a normal read/write operation (i.e., the memory cells are abnormal), the abnormal memory cells may be replaced by the redundant memory cells to ensure that the memory can work normally. After the redundant memory cells match the address of the abnormal memory cells, a matching signal is generally produced. The matching signal needs to be transmitted in time to ensure the correct execution of the read/write operation.

### SUMMARY

In view of this, the embodiments of the present disclosure provide a defect repair circuit and a memory to reduce the transmission delay of a matching signal and improve the transmission efficiency of the matching signal.

The present disclosure relates to the field of semiconductors, and in particular to a defect repair circuit and a memory.

The technical solutions of the present disclosure are implemented as follows:

In a first aspect, a defect repair circuit and a memory are provided according to the embodiments of the present disclosure. The defect repair circuit includes a matching module, a bus, and a transmission processing module. The matching module is connected to the bus and configured to receive a target address and a plurality of defect addresses, match the target address with the plurality of defect addresses respectively to generate a plurality of matching result signals, generate at least one matching signal according to the plurality of matching result signals, and transmit the at least one matching signal to the transmission processing module through the bus. The target address is an address to be accessed by the current operation. The transmission processing module is connected to the bus and configured to receive at the least one matching signal through the bus and generate and output a repair indication signal according to the at least one matching signal. When any one of the at least one matching signal is at an active level, indicating that the target address is successfully matched with one of the plurality of defect addresses, the repair indication signal is set to an active level and output. Alternatively, when all of the at least one matching signal is at an inactive level, indicating that the target address fails to match any of the plurality of defect addresses, the repair indication signal is set to an inactive level and output.

In the above solution, the matching module includes a plurality of matching submodules; each of the plurality of matching submodules corresponds to one memory area, and each memory area corresponds to one set of redundant addresses. Each of the plurality of matching submodules is configured to match the target address with all defect addresses in a corresponding memory area respectively to generate a plurality of matching result signals, and generate one matching signal according to the plurality of matching result signals. The bus includes a plurality of signal transmission buses, the plurality of signal transmission buses are in a one-to-one correspondence with the plurality of matching submodules; each of the plurality of signal transmission buses is configured to transmit one matching signal generated by a corresponding matching submodule.

In the above solution, each of the plurality of matching submodules includes a plurality of matching processing units, and the plurality of matching processing units are all connected to one corresponding signal transmission bus. Each of the plurality of matching processing units is configured to latch one corresponding defect address, match the target address with the latched defect address after receiving the target address, and generate and output the matching result signal. When the target address is the same as the latched defect address, indicating that the target address is successfully matched, the matching result signal at an active level is generated, and the matching result signal at the active level is output as the matching signal to a corresponding signal transmission bus. Alternatively, when the target address is different from the latched defect address, indicating that the target address is not successfully matched, the matching result signal at an inactive level is generated, and the matching result signal at the inactive level is output as the matching signal to a corresponding signal transmission bus.

In the above solution, each of the plurality of matching processing units includes a plurality of latch comparison subunits and a matching result generation unit. Each of the plurality of latch comparison subunits is configured to receive one corresponding target address bit from the target address and one corresponding defect address bit from the defect address and generate one comparison result signal according to the target address bit and the defect address bit. The matching result generation unit is connected to the plurality of latch comparison subunits and configured to receive a plurality of corresponding comparison result signals and perform a logic operation on the plurality of comparison result signals to generate the matching result signal.

In the above solution, each of the plurality of latch comparison subunits includes a latch and a comparator. The latch is configured to receive and latch one corresponding defect address bit. The comparator is connected to the latch and configured to receive one corresponding target address bit and the latched defect address bit, compare the target address bit with the defect address bit, and output one corresponding comparison result signal.

In the above solution, the transmission processing module includes a plurality of transmission processing submodules and a logic operation circuit; the plurality of transmission processing submodules are connected to the plurality of matching submodules in a one-to-one correspondence manner through the plurality of signal transmission buses. Each of the plurality of transmission processing submodules is configured to receive a corresponding storage area enable signal, process the matching signal transmitted on a corresponding signal transmission bus according to the storage area enable signal, and then output the processed matching signal from an output terminal thereof. The logic operation circuit is connected to the plurality of transmission processing submodules and configured to perform a logic operation on a plurality of processed matching signals to generate the repair indication signal. In the case where any one of the plurality of processed matching signals is at an active level, the logic operation circuit outputs the repair indication signal at an active level, and in the case where each of the plurality of processed matching signals is at an inactive level, the logic operation circuit outputs the repair indication signal at an inactive level.

In the above solution, the transmission processing submodule includes a positive feedback circuit and a holding circuit. The positive feedback circuit is connected to a corresponding signal transmission bus and configured to, in response to the storage area enable signal at an active level, connect the corresponding signal transmission bus to a first power supply when the matching signal transmitted on the corresponding signal transmission bus is at an active level, where the level of the first power supply is the same as the active level of the matching signal. The holding circuit is connected to the corresponding signal transmission bus and configured to, in response to the storage area enable signal at an active level, connect the corresponding signal transmission bus to a second power supply when the matching signal transmitted on the corresponding signal transmission bus is at an inactive level, where the level of the second power supply is the same as the inactive level of the matching signal.

In the above solution, the logic operation circuit includes a first NAND gate and a first inverter. A plurality of input terminals of the first NAND gate are respectively connected to output terminals of a plurality of transmission processing submodules for receiving the plurality of processed matching signals. An output terminal of the first NAND gate is connected to an input terminal of the first inverter. An output terminal of the first inverter outputs the repair indication signal.

In the above solution, the holding circuit includes a second inverter, a second NAND gate, and a second transistor. An input terminal of the second inverter receives the storage area enable signal, and an output terminal of the second inverter is connected to the positive feedback circuit and one input terminal of the second NAND gate. The other input terminal of the second NAND gate is connected to a corresponding signal transmission bus. An output terminal of the second NAND gate is connected to a gate of the second transistor. A source of the second transistor is connected to the second power supply, and a drain of the second transistor is connected to the corresponding signal transmission bus. The drain of the second transistor serves as an output terminal of the transmission processing submodule.

In the above solution, the positive feedback circuit includes a NOR gate and a first transistor. One input terminal of the NOR gate is connected to the corresponding signal transmission bus, and the other input terminal of the NOR gate is connected to the output terminal of the second inverter. An output terminal of the NOR gate is connected to a gate of the first transistor. A source of the first transistor is connected to the first power supply, and a drain of the first transistor is connected to the corresponding signal transmission bus. The drain of the first transistor serves as an output terminal of the transmission processing submodule.

In the above solution, the defect repair circuit further includes a repair module. The repair module is connected to the transmission processing module and configured to receive the repair indication signal and replace the address to be accessed by the current operation from the target address to a corresponding redundant address in the case where the repair indication signal is at an active level.

In the above solution, the defect repair circuit further includes a defect information storage module and a reset module. The defect information storage module is connected to the matching module and configured to store the defect address and transmit the defect address to the matching module. The reset module is connected to the bus and configured to restore the bus to the initial level.

In the above solution, the reset module includes a plurality of third transistors and a plurality of fourth transistors. A source of each of the plurality of third transistors is connected to a power supply, a drain of each of the plurality of third transistors is connected to one corresponding signal transmission bus, and a gate of each of the plurality of third transistors is configured to receive a first reset signal; the first reset signal is a signal produced when the defect repair circuit receives a new target address. A source of each of the plurality of fourth transistors is connected to a power supply, a drain of each of the plurality of fourth transistors is connected to one corresponding signal transmission bus, and a gate of each of the plurality of fourth transistors is configured to receive a second reset signal; the second reset signal is a signal produced when the defect repair circuit is powered on.

In the above solution, the active level of the storage area enable signal is a high level, and active levels of the matching result signal, the repair indication signal, and the matching signal are all low levels. The first transistor is a PMOS transistor, and the second transistor is an NMOS transistor.

In the above solution, the matching module further includes a plurality of redundant rows/columns; the plurality of redundant rows/columns are in a one-to-one correspondence with the plurality of the defect addresses. The matching module is further configured to direct, according to the matching result signal, the current operation to the redundant row/column corresponding to the defect address matching the target address.

In a second aspect, a memory is further provided according to the embodiments of the present disclosure. The memory includes the defect repair circuit according to the above solution.

### BRIEF DESCRIPTION OF DRAWINGS

FIG. 1 is a first schematic structural diagram of a defect repair circuit according to an embodiment of the present disclosure;

FIG. 2 is a second schematic structural diagram of a defect repair circuit according to an embodiment of the present disclosure;

FIG. 3 is a third schematic structural diagram of a defect repair circuit according to an embodiment of the present disclosure;

FIG. 4 is a fourth schematic structural diagram of a defect repair circuit according to an embodiment of the present disclosure;

FIG. 5 is a fifth schematic structural diagram of a defect repair circuit according to an embodiment of the present disclosure;

FIG. 6 is a sixth schematic structural diagram of a defect repair circuit according to an embodiment of the present disclosure;

FIG. 7 is a seventh schematic structural diagram of a defect repair circuit according to an embodiment of the present disclosure;

FIG. 8 is an eighth schematic structural diagram of a defect repair circuit according to an embodiment of the present disclosure;

FIG. 9 is a ninth schematic structural diagram of a defect repair circuit according to an embodiment of the present disclosure;

FIG. 10 is a tenth schematic structural diagram of a defect repair circuit according to an embodiment of the present disclosure; and

FIG. 11 is a schematic structural diagram of a memory according to an embodiment of the present disclosure.

### DETAILED DESCRIPTION

To make the objectives, technical solutions, and advantages of the present disclosure clearer, the technical solutions of the present disclosure are further elaborated below with reference to the drawings and embodiments. The described embodiments should not be construed as limiting the present disclosure, and all other embodiments obtained by a person of ordinary skill in the art without making creative efforts fall within the protection scope of the present disclosure.

In the following description, reference is made to “some embodiments” which describe subsets of all possible embodiments, but it can be understood that “some embodiments” may be the same subset or different subsets of all possible embodiments, and may be combined with each other without conflict.

If the application document contains descriptions such as “first/second”, the following explanation is added: In the following description, the terms “first/second/third” are used merely to distinguish similar objects and do not imply a specific order of the objects. It can be understood that “first/second/third” may be interchanged with a specific order or sequence if permitted, such that the embodiments of the present disclosure described herein can be implemented in an order other than that shown or described herein.

Unless otherwise defined, all technical and scientific terms used herein have the same meaning as commonly understood by those skilled in the art to which the present disclosure belongs. The terms used herein are for the purpose of describing the embodiments of the present disclosure only and are not intended to limit the present disclosure.

In some implementations, a method for repairing a defect column (row) is as follows: Some redundant columns (rows) are set in a memory, and after a memory cell (Cell) is detected to be abnormal, the redundant row is used for replacing the whole row of the memory cells corresponding to the abnormal memory cell. Alternatively, the redundant column is used for replacing the whole column of the memory cells corresponding to the abnormal memory cell. In the repair process, the address of the abnormal memory cell needs to be stored, i.e., storing the defect address. Then, the stored defect address is called and matched with the address of the currently operated memory cell to produce a corresponding matching signal. Then, according to the received matching signal, the address where the read/write operation is performed is replaced from the defect address to the address of the redundant column (row). As such, after one redundant column or redundant row is matched with the defect address, the transmission speed of the corresponding matching signal is relatively low and the repair speed is reduced.

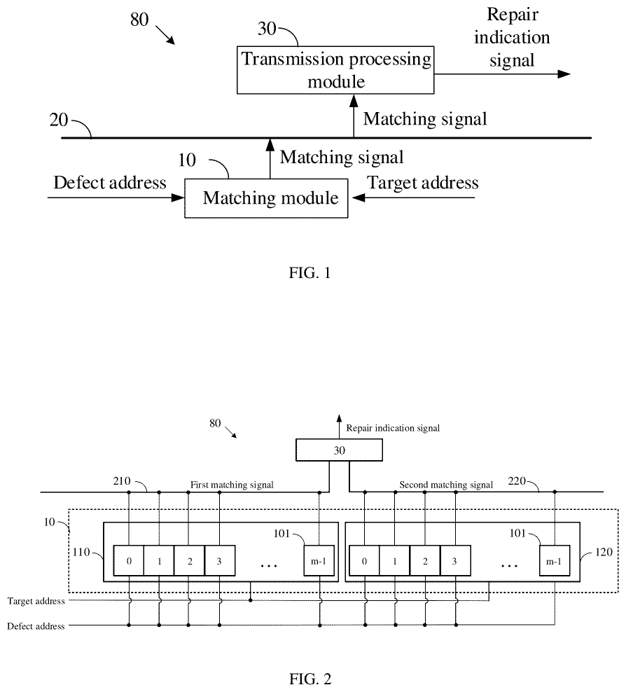

FIG. 1 is an optional schematic diagram of a defect repair circuit according to an embodiment of the present disclosure. As shown in FIG. 1, the defect repair circuit 80 includes a matching module 10, a bus 20, and a transmission processing module 30. The matching module 10 is connected to the bus 20 and configured to receive a target address and a plurality of defect addresses, match the target address with the plurality of defect addresses respectively to generate a plurality of matching result signals, generate at least one matching signal according to the plurality of matching result signals, and transmit the matching signal to the bus 20. The target address is the address to be accessed by the current operation. The transmission processing module 30 is connected to the bus 20 and configured to: receive at least one matching signal through the bus 20 and generate and output a repair indication signal according to the at least one matching signal. When any matching signal is at an active level, indicating that the target address is successfully matched with one of the plurality of defect addresses, the repair indication signal is set to an active level and output. Alternatively, when the matching signals are all at an inactive level, indicating that the target address fails to match any defect address, the repair indication signal is set to an inactive level and output.

In the embodiment of the present disclosure, referring to FIG. 1, the matching module 10 assigns the plurality of received defect addresses to a plurality of redundant row matching processing units (RRED) or a plurality of redundant column matching processing units (CRED) included therein. Each redundant row matching processing unit/redundant column matching processing unit receives one defect address and a target address. The target address is the address to be accessed by the current operation. The current operation may be a refresh operation, an activation operation, a read operation, or a write operation on the memory cell. The target address corresponding to the refresh operation and the activation operation is a row address and the target address corresponding to the read operation and the write operation is a column address. Then, the plurality of redundant row matching processing units/redundant column matching processing units complete the matching of the target address and the plurality of defect addresses to produce a plurality of corresponding matching result signals. The matching module 10 produces at least one matching signal based on the plurality of matching result signals generated by matching the plurality of defect addresses with the target address. The at least one matching signal is transmitted directly to the transmission processing module 30 through the bus 20.

Further, the transmission processing module 30 generates and outputs a repair indication signal according to the at least one matching signal. For example, in the case where any one of the plurality of matching signals indicates that the defect address and the target address are successfully matched, the transmission processing module 30 generates a low-level repair indication signal, and the low-level repair indication signal can be used to instruct the defect repair circuit 80 to perform defect repair. Alternatively, when the matching signals are all at an inactive level, indicating that the target address fails to match any defect address, the transmission processing module 30 generates a high-level repair indication signal.

It can be understood that the matching module is directly connected to the bus, the at least one matching signal produced by the matching module is directly transmitted to the transmission processing module through the bus, and there is no delay brought by other modules on the transmission path of the matching signal, thereby reducing the transmission delay of the matching signal. Additionally, one matching signal is produced based on the plurality of matching result signals generated by matching the plurality of defect addresses with the target address, to achieve the purpose of sharing a bus among the plurality of matching result signals, thereby reducing the burden on internal bus resources of the memory.

FIG. 2 is an optional schematic diagram of a defect repair circuit according to an embodiment of the present disclosure. In some embodiments of the present disclosure, the matching module 10 includes a plurality of matching submodules. Each matching submodule corresponds to one memory area, and each memory area corresponds to one set of redundant addresses. Each matching submodule is configured to match a target address with all defect addresses in a corresponding memory area respectively to generate a plurality of matching result signals, and generate one matching signal according to the plurality of matching result signals. The bus includes a plurality of signal transmission buses, and the plurality of signal transmission buses are in a one-to-one correspondence with the plurality of matching submodules. Each signal transmission bus is configured to transmit one matching signal generated by a corresponding matching submodule.

It should be noted that the memory area may be any one of a memory bank (bank), a half memory bank (half bank), a memory section (section), and a memory mat (mat).

In the embodiment of the present disclosure, the matching module may include a plurality of matching submodules, and each matching submodule corresponds to one memory area. A plurality of signal transmission buses are in a one-to-one correspondence with a plurality of matching submodules. For example, referring to FIG. 2, the matching module 10 includes a first matching submodule 110 and a second matching submodule 120. The memory areas corresponding to the first matching submodule 110 and the second matching submodule 120 are both half memory banks. The bus includes a first signal transmission bus 210 and a second signal transmission bus 220.

In the embodiment of the present disclosure, the bus includes a plurality of signal transmission buses, and the plurality of signal transmission buses are in a one-to-one correspondence with the plurality of matching submodules. Each signal transmission bus is configured to transmit one matching signal generated by a corresponding matching submodule. For example, with continued reference to FIG. 2, the bus includes the first signal transmission bus 210 and the second signal transmission bus 220. The first signal transmission bus 210 corresponds to the first matching submodule 110 and transmits a first matching signal produced by the first matching submodule 110. The second signal transmission bus 220 corresponds to the second matching submodule 120 and transmits a second matching signal produced by the second matching submodule 120.

In the embodiment of the present disclosure, each matching submodule is configured to match a target address with all defect addresses in a corresponding memory area respectively to generate a plurality of matching result signals, and generate one matching signal according to the plurality of matching result signals. For example, with continued reference to FIG. 2, the first matching submodule 110 includes m matching processing units 101, where m represents a positive integer. The m matching processing units 101 are all connected to the first signal transmission bus 210 and correspondingly generate m matching result signals. The first matching submodule 110 generates a first matching signal according to the generated m matching result signals.

In the embodiment of the present disclosure, with continued reference to FIG. 2, each matching submodule corresponds to one memory area, and each memory area corresponds to a plurality of defect addresses. The defect repair circuit 80 transmits all the defect addresses corresponding to each memory area to a corresponding matching submodule. That is, the matching submodule sequentially distributes all the received defect addresses to the plurality of matching processing units 101, and thus all the defect addresses corresponding to the memory area are respectively latched into one corresponding matching processing unit 101. Each matching processing unit 101 matches the received one defect address with the address to be accessed by the current operation (i.e. the target address) to generate a corresponding matching signal. As a result, each matching submodule can match the target address with all the defect addresses in a corresponding memory area to generate a matching signal. As such, each matching submodule corresponds to one memory area and can independently perform address matching and output a matching signal. That is, the matching module is provided with a plurality of parallel memory areas.

In the embodiment of the present disclosure, with continued reference to FIG. 2, each matching submodule receives a corresponding storage area enable signal, and determines whether to perform a matching operation between a target address and a defect address in a corresponding matching submodule according to the enabled state of the storage area enable signal. When the corresponding storage area enable signal is at an active level, the matching operation between the target address and the defect address in the corresponding matching submodule is executed to generate and output a matching signal; when the corresponding storage area enable signal is at an inactive level, the matching operation between the target address and the defect address in the corresponding matching submodule is not executed, and the matching signal is not generated. For example, when the storage area enable signal corresponding to the first matching submodule 110 is at an active level (high level), the memory area where the first matching submodule 110 is located is in an enabled state, the first matching submodule 110 performs a matching operation between the received target address and the defect address, and thus output a matching signal with a corresponding level state according to the matching result of the target address. When the storage area enable signal corresponding to the second matching submodule 120 is at an inactive level (low level), the memory area where the second matching submodule 120 is located is in a disabled state, the second matching submodule 120 does not generate a matching signal, and the corresponding second signal transmission bus 220 thereof maintains output at an inactive level (high level). As such, in the present disclosure, a corresponding matching submodule (e.g., the matching submodule corresponds to a half memory bank) and a redundant row/redundant column can be activated, thereby avoiding the activation of the entire matching module (e.g., the matching module corresponds to a memory bank), which reduces power consumption and also avoids contention conflicts.

It should be noted that each memory area corresponds to one set of redundant addresses; the number of redundant addresses in each set should be greater than or equal to the number of defect addresses corresponding to each memory area. The redundant address here may be a redundant row address or a redundant column address. When a newly added defect address exists in a memory area corresponding to a matching submodule, the matching submodule latches the newly added defect address in an unused matching processing unit.

It can be understood that the matching module is provided with a plurality of parallel memory areas, and each matching submodule matches the target address with all defect addresses in a corresponding memory area. As such, in the embodiment of the present disclosure, the corresponding memory area can be selected to be activated according to the result of address matching, thereby avoiding the activation of the entire matching module, which reduces energy consumption and also avoids contention conflicts. Additionally, for one memory area, only one bus is needed in the embodiment of the present disclosure, thereby reducing the burden on bus resources.

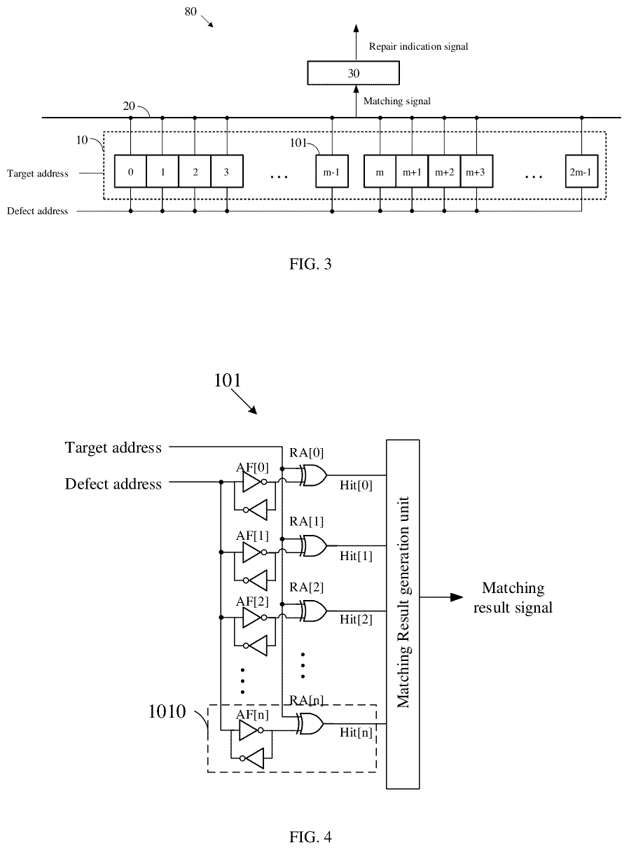

FIG. 3 is another optional schematic diagram of a defect repair circuit according to an embodiment of the present disclosure. Referring to FIG. 3, when the memory area corresponding to the matching module 10 is one memory bank, all matching processing units 101 included in the matching module 10 may also be directly connected to the bus 20. Thus, each matching signal produced by each matching processing unit 101 can be directly transmitted to the transmission processing module 30 through one bus 20. As such, the burden on bus resources is further reduced.

In some embodiments of the present disclosure, referring to FIG. 2, each matching submodule includes a plurality of matching processing units 101. The plurality of matching processing units 101 are all connected to one corresponding signal transmission bus. Each matching processing unit 101 is configured to latch one corresponding defect address, match the target address with the latched defect address after receiving the target address, and generate and output a matching result signal. When the target address is the same as the latched defect address, indicating that the target address is successfully matched, a matching result signal at an active level is generated, and the matching result signal is output as a matching signal to a corresponding signal transmission bus. Alternatively, when the target address is different from the latched defect address, indicating that the target address is not successfully matched, a matching result signal at an inactive level is generated, and the matching signal output to the corresponding signal transmission bus remains at an inactive level.

In the embodiment of the present disclosure, with continued reference to FIG. 2, the matching module 10 includes a plurality of matching processing units 101. The matching processing unit 101 corresponds to a redundant row or a redundant column. Each matching processing unit 101 is configured to receive an address to be accessed by the current operation (i.e., a target address), and correspondingly receive one defect address. Each matching processing unit 101 matches the received one defect address with the target address, i.e., compares whether the defect address is the same as the target address. Further, the matching processing unit 101 generates a corresponding matching result signal according to the comparison result between the defect address and the target address. For example, in the case where the target address and the defect address received by the matching processing unit 101 are the same, the matching processing unit 101 outputs a matching result signal at a low level.

In the embodiment of the present disclosure, with continued reference to FIG. 2, the first matching submodule 110 and the second matching submodule 120 both include m matching processing units 101. Each matching processing unit 101 receives and latches one defect address assigned by the matching submodule, and matches the latched defect address with the received target address to output a corresponding matching signal. The active level may be a low level and the inactive level may be a high level. For example, the target address and the defect address include 16 address bits. For one matching processing unit 101, when the 16 address bits of the received target address and the latched defect address are all the same, indicating a successful address match, the matching processing unit 101 will generate a matching signal at a low level and output the matching signal to a corresponding signal transmission bus. Accordingly, for a matching processing unit 101, when there is at least one different address bit in the 16 address bits of the received target address and the latched defect address, indicating an unsuccessful address match, the matching processing unit 101 maintains the matching signal output to the corresponding signal transmission bus at a high level.

It can be understood that the matching processing units are all directly connected to the bus and connected to the transmission processing module through the bus. As such, compared with the arrangement mode in some implementations where the matching module is divided into a plurality of levels, the transmission levels of the matching signal can be reduced by adopting the embodiments of the present disclosure, thereby reducing the transmission delay of the matching signal. Moreover, the connection or disconnection of some matching processing units does not affect the transmission of the matching signal, such that the number of the matching processing units may be adjusted as needed, thereby improving the compatibility of the defect repair circuit. Additionally, each matching processing unit has the same transmission level, and the timings of a plurality of matching signals transmitted to the transmission processing module are matched with one another, thereby avoiding the problem of race hazard.

In some embodiments of the present disclosure, referring to FIG. 4, each matching processing unit 101 includes: a plurality of latch comparison subunits 1010 and a matching result generation unit 1020. Each latch comparison subunit 1010 is configured to receive one target address bit corresponding to a corresponding target address and one defect address bit corresponding to a defect address and generate a comparison result signal according to the target address bit and the defect address bit. The matching result generation unit 1020 is connected to the plurality of latch comparison subunits 1010 and configured to receive a plurality of corresponding comparison result signals and perform a logic operation on the plurality of comparison result signals to generate a matching result signal.

In the embodiment of the present disclosure, referring to FIG. 4, to ensure the uniqueness of the address, the row address information or the column address information of the memory generally includes a plurality of address bits. Therefore, the defect address and the target address both include a plurality of address bits. For example, the number of address bits of the defect address and the target address is n, where n is a positive integer. Each latch comparison subunit 1010 receives one target address bit of a corresponding target address and one defect address bit of a defect address and generates a comparison result signal of the target address bit and the defect address bit. The plurality of latch comparison subunits included in each matching processing unit 101 compare the plurality of address bits of the defect address and the target address and input the generated comparison result signal of the plurality of address bits to the matching result generation unit 1020.

In the embodiment of the present disclosure, with continued reference to FIG. 4, the matching result generation unit 1020 is connected to a plurality of latch comparison subunits 1010, receives a plurality of corresponding comparison result signals, and performs a logic operation on the plurality of comparison result signals to generate a corresponding matching result signal of the defect address and target address. For example, in the case where address bits of the defect address and the target address received by the matching processing unit 101 are all the same, the matching processing unit 101 outputs an active-level matching result signal.

Further, in the case where address bits of the defect address and the target address received by the matching processing unit 101 are all the same, the defect address and the target address are successfully matched, and the corresponding matching submodule outputs an active-level matching signal. In the case where there is at least one different address bit in the defect address and the target address received by the matching processing unit 101, the defect address and the target address are not successfully matched, and the corresponding matching submodule outputs an inactive-level matching signal.

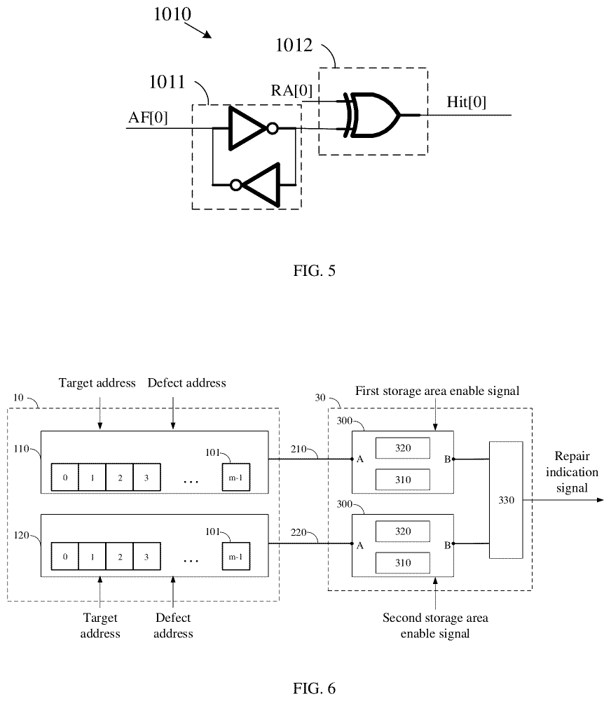

In some embodiments of the present disclosure, referring to FIG. 5, each latch comparison subunit 1010 includes a latch 1011 and a comparator 1012. The latch 1011 is configured to receive and latch one corresponding defect address bit. The comparator 1011, connected to the latch 1012, is configured to receive one corresponding target address bit and one latched defect address bit, compare the target address bit with the defect address bit, and output one corresponding comparison result signal.

In the embodiment of the present disclosure, with continued reference to FIG. 5, the comparator 1012 may be an exclusive-OR gate. The latch 1011 may be two inverters connected end-to-end. The latch 1011 receives one defect address bit of the defect address. For example, the defect address bit of the defect address received by the latch 1011 is AF[0]. One input terminal of the comparator 1012 receives one target address bit corresponding to the target address. For example, the target address bit of the target address received by the comparator 1012 is RA[0]. The other input terminal of the comparator 1012 is connected to the latch 1011 and receives the one defect address bit of the defect address received by the comparator 1012. Thus, the latch comparison subunit 1010 receives the defect address bit AF[0] and the target address bit RA[0], compares the defect address bit AF[0] with the target address bit RA[0], and correspondingly generates a comparison result signal HIT[0] of the current address bit.

In some embodiments of the present disclosure, referring to FIG. 6, the transmission processing module 30 includes a plurality of transmission processing submodules 300 and a logic operation circuit 330. The plurality of transmission processing submodules 300 are connected to the plurality of matching submodules in a one-to-one correspondence manner through a plurality of signal transmission buses. Each transmission processing submodule 300 is configured to receive a corresponding storage area enable signal, process the matching signal transmitted on a corresponding signal transmission bus according to the storage area enable signal, and then output the matching signal from the output terminal B thereof. The logic operation circuit 330 is connected to the plurality of transmission processing submodules 300 and configured to perform a logic operation on a plurality of processed matching signals to generate a repair indication signal. In the case where any matching signal is at an active level, the logic operation circuit 330 outputs the repair indication signal at an active level. Additionally, in the case where each matching signal is at an inactive level, the logic operation circuit 330 outputs the repair indication signal at an inactive level.

In the embodiment of the present disclosure, with continued reference to FIG. 6, the transmission processing module 30 includes a plurality of transmission processing submodules 300. The plurality of transmission processing submodules 300 are connected to the plurality of matching submodules in a one-to-one correspondence manner through the plurality of signal transmission buses. The signal transmission bus is connected to the input terminal A of the transmission processing submodule 300. For example, the first matching submodule 110 is connected to a corresponding transmission processing submodule 300 through a first signal transmission bus 210; the second matching submodule 120 is connected to a corresponding transmission processing submodule 300 through a second signal transmission bus 220.

In the embodiment of the present disclosure, with continued reference to FIG. 6, each transmission processing submodule 300 is configured to receive a corresponding storage area enable signal, process the matching signal transmitted on a corresponding signal transmission bus according to the storage area enable signal, and then output the matching signal from the output terminal B thereof. For example, the matching signal correspondingly received by the first signal transmission bus 210 is a first matching signal, and the storage area enable signal received by the transmission processing submodule corresponding to the first signal transmission bus 210 is a first storage area enable signal. The transmission processing submodule 300 processes the first matching signal transmitted on the first signal transmission bus 210 according to the first storage area enable signal. Then, the processed first matching signal is output to the logic operation circuit 330 from the output terminal B of the transmission processing submodule 300.

It should be noted that referring to FIG. 6, input terminals A and output terminals B of the plurality of transmission processing submodules 300 may all be connected to the signal transmission buses. Alternatively, each signal transmission bus is divided into two segments, the input terminals A of the plurality of transmission processing submodules 300 may all be connected to one segment of each signal transmission bus, and the output terminals B transmit the processed matching signal to the logic operation circuit 330 through the other segment of each signal transmission bus, which are not limited herein.

In the embodiment of the present disclosure, with continued reference to FIG. 6, in the case where one of the plurality of defect addresses latched by any matching submodule is successfully matched with the received target address, the matching signal generated by the matching submodule is at an active level. Then, the matching submodule that is successfully matched transmits the active-level matching signal to the transmission processing module 30 through a corresponding signal transmission bus. For example, in the case where one of the plurality of defect addresses latched by the first matching submodule 110 is successfully matched with the received target address, the first matching submodule 110 outputs an active-level first matching signal to the transmission processing module 30 through the first signal transmission bus 210.

Further, based on the received active-level matching signal, the transmission processing submodule 300 of the transmission processing module 30 connects the signal transmission bus that delivers the active-level matching signal to a first power supply. For example, the first power supply is a ground terminal, and in the case where the first matching signal output by the first matching submodule 110 is at a low level, the transmission processing module 30 connects the signal transmission bus 210 to the ground terminal. Thus, the level state of the first matching signal remains unchanged and the voltage of the first matching signal is lowered, such that the first matching signal can be transmitted to the logic operation circuit 330 more quickly. Then, the logic operation circuit 330 performs a logic operation on the plurality of processed matching signals and generates and outputs low-level repair indication signals.

In the embodiment of the present disclosure, with continued reference to FIG. 6, in the case where none of the plurality of matching submodules 100 connected to the transmission processing module 30 are successfully matched, the matching signals generated by the plurality of matching submodules 100 are all at an inactive level. Then, the plurality of matching submodules 100 transmit the plurality of inactive-level matching signals to the transmission processing module 30 through corresponding signal transmission buses. For example, the matching module 10 includes a first matching submodule 110 and a second matching submodule 120. The memory area where the first matching submodule 110 is located is in an enabled state, and if the first matching submodule 110 is not successfully matched, an inactive-level first matching signal is correspondingly output to the transmission processing module 30. The memory area where the second matching submodule 120 is located is in a disabled state, and the second matching submodule 120 does not generate a matching signal. Thus, the corresponding second signal transmission bus 220 of the second matching submodule maintains output at an inactive level (high level).

Further, based on the received inactive-level first matching signal, the transmission processing submodule 300 of the transmission processing module 30 connects the signal transmission bus corresponding to the first matching submodule 110 in an enabled state to a second power supply. For example, the second power supply is a power supply terminal, and in the case where the first matching signal output by the first matching submodule 110 is at a high level, the transmission processing module 30 connects the first signal transmission bus 210 to the power supply terminal. Thus, the level state of the first matching signal remains unchanged and the voltage of the first matching signal is increased, such that the first matching signal can be transmitted to the logic operation circuit 330 more quickly. Then, the logic operation circuit 330 performs a logic operation on the plurality of processed matching signals, and generates and outputs high-level repair indication signals.

It can be understood that based on the received matching signal of the corresponding matching submodule, the transmission processing submodule connects the signal transmission bus corresponding to the matching submodule to a corresponding power supply. As such, the transmission speed of the matching signal is further accelerated, thereby reducing the transmission delay of the matching signal.

FIG. 7 is an optional schematic diagram of a defect repair circuit according to an embodiment of the present disclosure. It should be noted that the bus 20 includes a plurality of signal transmission buses. In FIG. 7, as an example, the bus 20 includes a first signal transmission bus 210 and a second signal transmission bus 220. The first signal transmission bus 210 and the second signal transmission bus 220 both include two separate segments. Additionally, one of the segments is configured to connect the matching submodule to the input terminal A of the transmission processing submodule, and the other segment is configured to connect the output terminal B of the transmission processing submodule to the logic operation circuit 330. The matching signal correspondingly received by the first signal transmission bus 210 is the first matching signal, and the storage area enable signal received by the transmission processing submodule 300 corresponding to the first signal transmission bus 210 is the first storage area enable signal; accordingly, the matching signal correspondingly received by the second signal transmission bus 220 is the second matching signal, and the storage area enable signal received by the transmission processing submodule 300 corresponding to the second signal transmission bus 220 is the second storage area enable signal. The first power supply 313 may be the ground terminal and the second power supply 324 may be the power supply terminal.

In some embodiments of the present disclosure, referring to FIG. 7, the transmission processing submodule 300 includes a positive feedback circuit 310 and a holding circuit 320. The positive feedback circuit is connected to a corresponding signal transmission bus and configured to, in response to the storage area enable signal at an active level, connect the corresponding signal transmission bus to a first power supply 313 when the matching signal transmitted on the corresponding signal transmission bus is at an active level, where the level of the first power supply 313 is the same as the active level of the matching signal. The holding circuit is connected to the corresponding signal transmission bus and configured to, in response to the storage area enable signal at an active level, connect the corresponding signal transmission bus to a second power supply 324 when the matching signal transmitted on the corresponding signal transmission bus is at an inactive level, where the level of the second power supply 324 is the same as the inactive level of the matching signal.

In the embodiment of the present disclosure, referring to FIG. 7, in the case where the storage area enable signal is at an inactive level (low level) and the matching signal transmitted by the signal transmission bus is at an inactive level (high level), the holding circuit 320 is in an operating state, thus connecting the corresponding signal transmission bus to the second power supply 324. For example, the first storage area enable signal is at a low level, the first matching signal is at a high level, and the second power supply 324 is the power supply terminal. Therefore, the second transistor 323 is in an on state, and the first signal transmission bus 210 is connected to the power supply terminal. Thus, the signal transmitted to the logic operation circuit 330 by the first signal transmission bus 210 is at a high level. That is, the holding circuit 320 is configured to, in response to the storage area enable signal at an active level (high level), connect the corresponding signal transmission bus to the second power supply (power supply terminal) when the matching signal transmitted on the corresponding signal transmission bus is at an inactive level (high level).

In the embodiment of the present disclosure, with continued reference to FIG. 7, in the case where the storage area enable signal is at an active level (high level) and the matching signal transmitted by the signal transmission bus is at an inactive level (high level), neither the holding circuit 320 nor the positive feedback circuit 310 can be in an operating state. For example, the first storage area enable signal is at a high level, and the first matching signal is at a high level. Therefore, the first transistor 312 and the second transistor 323 are in an off state. Thus, the signal transmitted to the logic operation circuit 330 by the first signal transmission bus 210 is always at a high level.

In the embodiment of the present disclosure, with continued reference to FIG. 7, in the case where the storage area enable signal is at an active level (high level) and the matching signal transmitted by the signal transmission bus is at an active level (low level), the positive feedback circuit 310 is in an operating state, thus connecting the corresponding signal transmission bus 200 to the first power supply 313. For example, the first storage area enable signal is at a high level, the first matching signal is at a low level, and the first power supply 313 is the ground terminal. Therefore, the first transistor 312 is in an on state, and the first signal transmission bus 210 is connected to the ground terminal. Thus, the signal output to the logic operation circuit 330 by the first signal transmission bus 210 is at a low level. That is, the positive feedback circuit 310 is configured to, in response to the storage area enable signal at an active level (high level), connect the corresponding signal transmission bus to the first power supply (ground terminal) when the matching signal transmitted on the corresponding signal transmission bus is at an active level (low level).

In the embodiment of the present disclosure, with continued reference to FIG. 7, in the case where the storage area enable signal is at an inactive level (low level) and the matching signal transmitted by the signal transmission bus is at an active level (low level), neither the holding circuit 320 nor the positive feedback circuit 310 can be in an operating state. For example, the first storage area enable signal is at a low level, and the first matching signal is at a low level. Therefore, the first transistor 312 and the second transistor 323 are in an off state. Thus, the signal transmitted to the logic operation circuit 330 by the first signal transmission bus 210 is always at a high level.

In the embodiment of the present disclosure, with continued reference to FIG. 7, the input terminal A and the output terminal B of the transmission processing submodule 300 are respectively connected to two segments of a corresponding signal transmission bus. In the case where the storage area enable signal is at an active level (high level), the processed matching signal output by the output terminal B is at the same level as the matching signal at the input terminal A. In the case where the storage area enable signal is at an inactive level (low level), the processed matching signal output by the output terminal B remains at an inactive level (high level).

In the embodiment of the present disclosure, with continued reference to FIG. 7, in the case where the matching between the matching signal and the storage area enable signal is abnormal, the corresponding signal transmission bus is not connected to the first power supply or the second power supply, the output terminal B of the transmission processing submodule 300 does not output a signal, and the signal transmission bus maintains the initial level (high level). As such, the process of generating the repair indication signal by the logic operation circuit 330 can be prevented from being interfered with by the abnormal matching between the matching signal and the storage area enable signal.

In the embodiment of the present disclosure, with continued reference to FIG. 7, in the case where the matching submodule is abnormal, the abnormal matching signal is not directly transmitted to the logic operation circuit 330. The matching signal output by the matching submodule is processed by the transmission processing submodule 300 before it can be transmitted to the logic operation circuit 330. Thus, the process of generating the repair indication signal by the logic operation circuit 330 can be prevented from being interfered with by the abnormal matching signal. For example, in the case where the first storage area enable signal is at an inactive level (low level), the corresponding matching submodule does not perform a matching operation on the target address. If the matching submodule is abnormal and outputs an active-level (low-level) first matching signal, then the first matching signal needs to be processed by the transmission processing submodule 300 before it can be transmitted to the logic operation circuit 330. Since the first storage area enable signal is at an inactive level (low level), the transmission processing submodule 300 connects the segment of the first signal transmission bus 210 corresponding to the output terminal B of the transmission processing module to the power supply terminal, regardless of whether the level state of the first matching signal is at a low level or at a high level. The existence of the abnormal first matching signal does not interfere with the level state of the signal output by the transmission processing submodule 300, thereby preventing the process of generating the repair indication signal by the logic operation circuit 330 from being interfered with by the abnormal first matching signal.

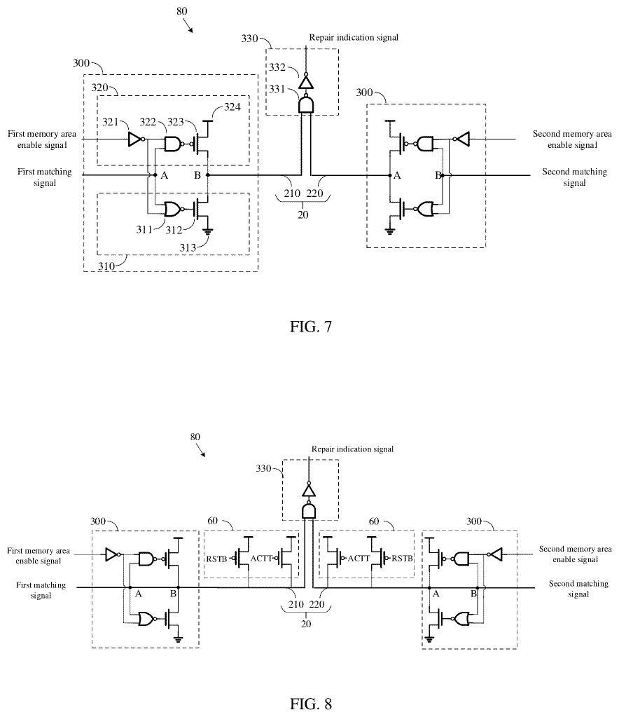

FIG. 8 is another optional schematic diagram of a defect repair circuit according to an embodiment of the present disclosure. It should be noted that the bus 20 includes a plurality of signal transmission buses. In FIG. 8, as an example, the bus 20 includes a first signal transmission bus 210 and a second signal transmission bus 220. The signal transmission bus does not include separate segments. The input terminal A and the output terminal B of the transmission processing submodule 300 are both connected to the corresponding first signal transmission bus 210 and second signal transmission bus 220.

In the embodiment of the present disclosure, referring to FIG. 8, in the process of processing the matching signal by the transmission processing submodule 300, the input terminal A of the transmission processing submodule 300 is connected to the output terminal B thereof. Therefore, the processed matching signal output by the output terminal B of the transmission processing submodule 300 exerts a positive feedback effect on the transmission processing submodule 300, thereby enabling rapid adjustment of the voltage of the matching signal. As such, the transmission speed of the matching signal is further accelerated, thereby reducing the transmission delay of the matching signal.

In some embodiments of the present disclosure, referring to FIG. 7, the logic operation circuit 330 includes a first NAND gate 331 and a first inverter 332. The input terminal of the first NAND gate 331 is connected to the plurality of signal transmission buses. The output terminal of the first NAND gate 331 is connected to the input terminal of the first inverter 332. The output terminal of the first inverter 332 outputs the repair indication signal.

In the embodiment of the present disclosure, the logic operation circuit 330 includes a first NAND gate 331 and a first inverter 332. The input terminal of the first NAND gate 331 is connected to the plurality of signal transmission buses, and the output terminal of the first NAND gate 331 is connected to the input terminal of the first inverter 332. Thus, when the signal outputted by any one of the plurality of signal transmission buses is at an active level, the logic operation circuit 330 outputs an active-level repair indication signal.

In some embodiments of the present disclosure, referring to FIG. 7, the holding circuit 320 includes a second inverter 321, a second NAND gate 322, and a second transistor 323. The input terminal of the second inverter 321 receives the storage area enable signal, and the output terminal of the second inverter 321 is connected to the positive feedback circuit 310 and one input terminal of the second NAND gate 322. The other input terminal of the second NAND gate 322 is connected to the bus 20, and the output terminal of the second NAND gate 322 is connected to the gate of the second transistor 323. The source of the second transistor 323 is connected to the second power supply 324, and the drain of the second transistor 323 is connected to the bus 20.

In the embodiment of the present disclosure, referring to FIG. 7, the holding circuit 320 includes a second inverter 321, a second NAND gate 322, and a second transistor 323. The input terminal of the second inverter 321 receives the storage area enable signal, and one input terminal of the second NAND gate 322 receives the matching signal. Thus, the holding circuit 320 can control the on and off of the second transistor 323 according to the level states of the corresponding storage area enable signal and matching signal, so as to select whether to connect the corresponding signal transmission bus to the second power supply 324.

In some embodiments of the present disclosure, referring to FIG. 7, the positive feedback circuit 310 includes a NOR gate 311 and a first transistor 312. One input terminal of the NOR gate 311 is connected to the bus 20, and the other input terminal of the NOR gate 311 is connected to the output terminal of the second inverter 321. The output terminal of the NOR gate 311 is connected to the gate of the first transistor 312. The source of the first transistor 312 is connected to the first power supply 313, and the drain of the first transistor 312 is connected to the bus 20.

In the embodiment of the present disclosure, referring to FIG. 7, one input terminal of the NOR gate 311 is connected to the bus 20 to receive the matching signal, and the other input terminal of the NOR gate 311 is connected to the second inverter 321 to receive the storage area enable signal inverted by the second inverter 321. Thus, the positive feedback circuit 310 can control the on and off of the first transistor 312 according to the level states of the corresponding storage area enable signal and matching signal, so as to select whether to connect the corresponding signal transmission bus to the first power supply 313.

In some embodiments of the present disclosure, referring to FIG. 7, the active level of the storage area enable signal is a high level, and active levels of the matching result signal, the repair indication signal, and the matching signal are all low levels. The first transistor 312 is a PMOS transistor, and the second transistor 323 is an NMOS transistor.

In the embodiment of the present disclosure, referring to FIG. 7, the first transistor 312 is a negative channel metal oxide semiconductor (Negative channel Metal Oxide Semiconductor, NMOS) transistor, and the second transistor 323 is a positive channel metal oxide semiconductor (Positive channel Metal Oxide Semiconductor, PMOS) transistor. Thus, in the case where the first power supply 313 is the ground terminal and the second power supply 324 may be the power supply terminal, the transmission processing submodule 300 connects the corresponding signal transmission bus to the ground terminal or the power supply terminal based on the received storage area enable signal and the matching signal. The matching signal transmitted by the signal transmission bus is at an active level (low level), and the transmission processing submodule 300 connects the signal transmission bus to the ground terminal. The matching signal transmitted by the signal transmission bus is at an inactive level (high level), and the transmission processing submodule 300 connects the signal transmission bus to the power supply terminal.

It should be noted that the active levels of the matching result signal, the repair indication signal, and the matching signal may be high levels. In the case where the active levels of the matching result signal, the repair indication signal, and the matching signal are high levels, the inactive levels of the matching result signal, the repair indication signal, and the matching signal correspond to low levels, the first power supply corresponds to the power supply terminal, and the second power supply corresponds to the ground terminal. When the memory area is in an enabled state, the active level of the corresponding storage area enable signal is a low level.

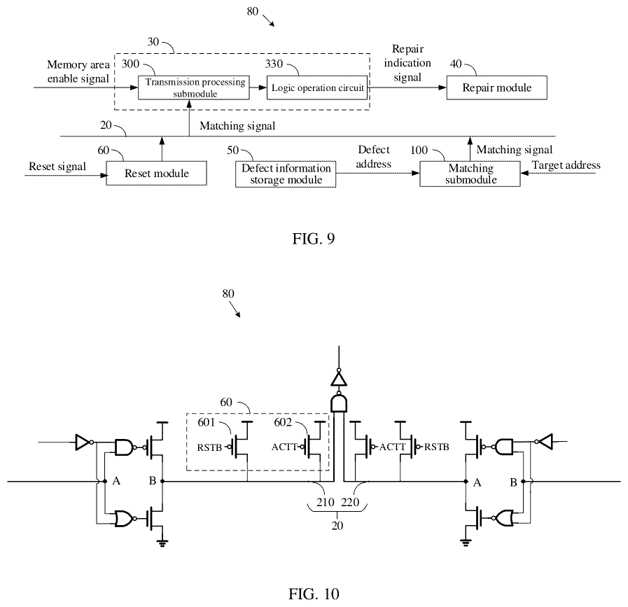

FIG. 9 is an optional schematic diagram of a defect repair circuit according to an embodiment of the present disclosure. In some embodiments of the present disclosure, referring to FIG. 9, the defect repair circuit 80 further includes a repair module 40, which is connected to the transmission processing module 30 and configured to receive the repair indication signal and replace the address to be accessed by the current operation from the target address to the corresponding redundant address in the case where the repair indication signal is at an active level.

In the embodiment of the present disclosure, referring to FIG. 9, the defect repair circuit 100 further includes a repair module 40. The repair module 40 is connected to the transmission processing module 30 and configured to receive the repair indication signal. In the case where one of the defect addresses received by any matching submodule 100 is the same as the target address, the matching submodule 100 outputs the matching signal to the transmission processing module through the bus 20. Then, the transmission processing module 30 outputs an active-level repair indication signal to the repair module 40 by using the transmission processing submodule 300 corresponding to each matching submodule 100. Then, the repair module 40 replaces the address to be accessed by the current operation from the target address to the redundant address of the corresponding matching subunit that has successfully matched in the matching submodule 100, so as to complete the repair of the current defect column/row.

In some embodiments of the present disclosure, referring to FIG. 9, the defect repair circuit 80 further includes a defect information storage module 50 and a reset module 60. The defect information storage module is connected to the matching module and configured to store the defect address and transmit the defect address to the matching submodule 100; the reset module is connected to the bus 20 and configured to restore the bus 20 to the initial level.

In the embodiment of the present disclosure, with continued reference to FIG. 9, the defect repair circuit 80 further includes a defect information storage module 50. The defect information storage module 50 may be connected to a plurality of matching submodules 100. The defect information storage module 50 transmits a plurality of defect addresses corresponding to a matching submodule 100 to the matching submodule 100. Thus, the matching submodule 100 can assign the received plurality of defect addresses and perform address matching.

It should be noted that the defect information storage module 50 may also be divided into corresponding defect information memory submodules, and the plurality of defect information memory submodules are in a one-to-one correspondence with the matching submodules 100.

In the embodiment of the present disclosure, with continued reference to FIG. 9, the defect repair circuit 80 further includes a reset module 60. The reset module 60 is connected to the bus 20, and upon receiving a corresponding reset signal, the reset module 60 restores the bus 20 to the initial level. For example, the initial level is an inactive level.

In some embodiments of the present disclosure, referring to FIG. 2, the matching module 10 further includes a plurality of redundant rows/columns. The plurality of redundant rows/columns are in a one-to-one correspondence with the plurality of defect addresses. The matching module 10 is further configured to direct, according to the matching result signal, the current operation to the redundant row/column corresponding to the defect address matching the target address.

In the embodiment of the present disclosure, with continued reference to FIG. 2, each redundant row/column may correspond to one matching processing unit 101, and each redundant row/column stores one defect address. Different redundant rows/columns store different defect addresses. For example, the redundant row/column corresponding to the first matching processing unit 101 stores the defect address 1, and the redundant row/column corresponding to the (m−1)-th matching processing unit 101 stores the defect address m−1. Thus, after the matching result signal indicates that the target address has been successfully matched, the matching module 10 can direct the operations such as the read operation, the refresh operation, and the write operation to the redundant row/column storing the corresponding defect address.

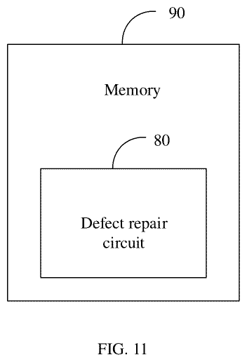

FIG. 10 is an optional schematic diagram of a defect repair circuit according to an embodiment of the present disclosure. It should be noted that the third transistor 601 and the fourth transistor 602 are both PMOS transistors.

In some embodiments of the present disclosure, referring to FIG. 10, the reset module 60 includes a plurality of third transistors 601 and a plurality of fourth transistors 602. The source of each third transistor 601 is connected to the power supply, and the drain of each third transistor 601 is correspondingly connected to one signal transmission bus. The gate of each third transistor 601 is configured to receive a first reset signal, and the first reset signal is a signal produced when the defect repair circuit receives a new bus enable command. The source of each fourth transistor 602 is connected to the power supply, and the drain of each fourth transistor 602 is correspondingly connected to one signal transmission bus. The gate of each fourth transistor 602 is configured to receive a second reset signal, and the second reset signal is a signal produced when the defect repair circuit 80 is powered on.

In the embodiment of the present disclosure, with continued reference to FIG. 10, the reset module 60 includes a plurality of third transistors 601 and a plurality of fourth transistors 602. The plurality of third transistors 601 and the plurality of fourth transistors 602 are in a one-to-one correspondence with a plurality of signal transmission buses, respectively. The first signal transmission bus 210 and the second signal transmission bus 220 are both connected to one third transistor 601 and one fourth transistor 602. That is, each signal transmission bus is connected to one third transistor 610 and one fourth transistor 602.

In the embodiment of the present disclosure, with continued reference to FIG. 10, the gate of the third transistor is configured to receive a first reset signal. For example, the first reset signal is an RSTB signal, and the RSTB signal is a signal produced when the defect repair circuit receives a new bus enable command. The source of the third transistor 601 is connected to the power supply terminal, and the drain of the third transistor 601 is connected to the bus 20. The gate of the fourth transistor 602 receives a second reset signal. For example, the second reset signal is an ACTT signal, and the second reset signal is a signal produced when the defect repair circuit 80 is powered on. The source of the fourth transistor 602 is connected to the power supply terminal, and the drain of the fourth transistor 602 is connected to the bus 20. When the RSTB signal is received at a low level, the third transistor 601 connects the bus 20 to the power supply terminal. When the ACTT signal is received at a low level, the fourth transistor 602 connects the bus 20 to the power supply terminal, thereby resetting the level of the corresponding signal transmission bus to the initial level. The initial level may generally be a high level. As such, the level of the signal transmission bus can be reset to a high level when the defect circuit is powered on or a new target address (a row address in a new activation command or a column address in a read/write operation command) is received, thereby preventing internal components of the matching module from being interfered with by an external circuit.

FIG. 11 is a schematic structural diagram of a memory 90 according to an embodiment of the present disclosure. As shown in FIG. 11, the memory 90 includes a defect repair circuit 80.

In some embodiments of the present disclosure, as shown in FIG. 11, the memory 90 is a dynamic random access memory.

It should be noted that in the present disclosure, the terms “include”, “comprise”, or any other variants thereof are intended to cover non-exclusive inclusion, such that a process, a method, an item, or an apparatus including a series of elements includes not only those elements but also other elements not explicitly listed, or elements inherent to such process, method, item, or apparatus. Without further limitation, an element defined by the phrase “including a . . . ” does not exclude the presence of additional identical elements in the process, method, item, or apparatus that includes the element.

The serial numbers of the embodiments of the present disclosure described above are for the purpose of describing only and do not represent the superiority or inferiority of the embodiments. The methods disclosed in the method embodiments provided in the present disclosure may be combined in any manner without conflict to obtain new method embodiments. The features disclosed in the product embodiments provided in the present disclosure may be combined in any manner without conflict to obtain new product embodiments. The features disclosed in the method or device embodiments provided in the present disclosure may be combined in any manner without conflict to obtain new method or device embodiments.

The above description is only the specific embodiments of the present disclosure, but the protection scope of the present disclosure is not limited thereto; changes or substitutions that any of those skilled in the art can easily think of within the technical scope disclosed by the present disclosure shall all fall within the protection scope of the present disclosure. Therefore, the protection scope of the present disclosure shall be subject to the protection scope of the claims.

What is claimed is:

1. A defect repair circuit, comprising: a matching module, a bus, and a transmission processing module, wherein
the matching module is connected to the bus and configured to receive a target address and a plurality of defect addresses, match the target address with the plurality of defect addresses respectively to generate a plurality of matching result signals, generate at least one matching signal according to the plurality of matching result signals, and transmit the at least one matching signal to the transmission processing module through the bus, wherein the target address is an address to be accessed by a current operation; and
the transmission processing module is connected to the bus and configured to receive the at least one matching signal through the bus and generate and output a repair indication signal according to the at least one matching signal,
wherein when any one of the at least one matching signal is at an active level, indicating that the target address is successfully matched with one of the plurality of defect addresses, the repair indication signal is set to an active level and output; or when all of the at least one matching signal is at an inactive level, indicating that the target address fails to match any of the plurality of defect addresses, the repair indication signal is set to an inactive level and output.

2. The defect repair circuit according to claim 1, wherein
the matching module comprises a plurality of matching submodules, each of the plurality of matching submodules corresponding to one memory area, and each memory area corresponding to one set of redundant addresses, wherein
each of the plurality of matching submodules is configured to match the target address with all defect addresses in a corresponding memory area respectively to generate a plurality of matching result signals, and generate one matching signal according to the plurality of matching result signals; and
the bus comprises a plurality of signal transmission buses, the plurality of signal transmission buses being in a one-to-one correspondence with the plurality of matching submodules, wherein
each of the plurality of signal transmission buses is configured to transmit one matching signal generated by a corresponding matching submodule.

3. The defect repair circuit according to claim 2, wherein
each of the plurality of matching submodules comprises a plurality of matching processing units, the plurality of matching processing units being all connected to one corresponding signal transmission bus, wherein
each of the plurality of matching processing units is configured to latch one corresponding defect address, match the target address with the latched defect address after receiving the target address, and generate and output the matching result signal, wherein
when the target address is the same as the latched defect address, indicating that the target address is successfully matched, the matching result signal at an active level is generated, and the matching result signal at the active level is output as the matching signal to a corresponding signal transmission bus; or
when the target address is different from the latched defect address, indicating that the target address is not successfully matched, the matching result signal at an inactive level is generated, and the matching result signal at the inactive level is output as the matching signal to a corresponding signal transmission bus.

4. The defect repair circuit according to claim 3, wherein each of the plurality of matching processing units comprises: a plurality of latch comparison subunits and a matching result generation unit, wherein
each of the plurality of latch comparison subunits is configured to receive one corresponding target address bit from the target address and one corresponding defect address bit from the defect address and generate one comparison result signal according to the target address bit and the defect address bit; and
the matching result generation unit is connected to the plurality of latch comparison subunits and configured to receive a plurality of corresponding comparison result signals and perform a logic operation on the plurality of comparison result signals to generate the matching result signal.

5. The defect repair circuit according to claim 4, wherein each of the plurality of latch comparison subunits comprises: a latch and a comparator, wherein
the latch is configured to receive and latch one corresponding defect address bit; and
the comparator is connected to the latch and configured to receive one corresponding target address bit and the latched defect address bit, compare the target address bit with the defect address bit, and output one corresponding comparison result signal.

6. The defect repair circuit according to claim 2, wherein the transmission processing module comprises: a plurality of transmission processing submodules and a logic operation circuit, the plurality of transmission processing submodules being connected to the plurality of matching submodules in a one-to-one correspondence manner through the plurality of signal transmission buses, wherein
each of the plurality of transmission processing submodules is configured to receive a corresponding storage area enable signal, process the matching signal transmitted on a corresponding signal transmission bus according to the storage area enable signal, and then output the processed matching signal from an output terminal thereof; and
the logic operation circuit is connected to the plurality of transmission processing submodules and configured to perform a logic operation on a plurality of processed matching signals to generate the repair indication signal, wherein in a case where any one of the plurality of processed matching signals is at an active level, the logic operation circuit outputs the repair indication signal at an active level, and in a case where each of the plurality of processed matching signals is at an inactive level, the logic operation circuit outputs the repair indication signal at an inactive level.

7. The defect repair circuit according to claim 6, wherein the transmission processing submodule comprises:
a positive feedback circuit, connected to a corresponding signal transmission bus and configured to, in response to the storage area enable signal at an active level, connect the corresponding signal transmission bus to a first power supply when the matching signal transmitted on the corresponding signal transmission bus is at an active level, wherein a level of the first power supply is the same as the active level of the matching signal; and
a holding circuit, connected to the corresponding signal transmission bus and configured to, in response to the storage area enable signal at an active level, connect the corresponding signal transmission bus to a second power supply when the matching signal transmitted on the corresponding signal transmission bus is at an inactive level, wherein a level of the second power supply is the same as the inactive level of the matching signal.

8. The defect repair circuit according to claim 6, wherein the logic operation circuit comprises: a first NAND gate and a first inverter, wherein
a plurality of input terminals of the first NAND gate are respectively connected to output terminals of the plurality of transmission processing submodules for receiving the plurality of processed matching signals; an output terminal of the first NAND gate is connected to an input terminal of the first inverter; and
an output terminal of the first inverter outputs the repair indication signal.

9. The defect repair circuit according to claim 7, wherein the holding circuit comprises: a second inverter, a second NAND gate, and a second transistor, wherein
an input terminal of the second inverter receives the storage area enable signal, and an output terminal of the second inverter is connected to the positive feedback circuit and one input terminal of the second NAND gate;
the other input terminal of the second NAND gate is connected to a corresponding signal transmission bus, and an output terminal of the second NAND gate is connected to a gate of the second transistor; and
a source of the second transistor is connected to the second power supply, and a drain of the second transistor is connected to the corresponding signal transmission bus;
the drain of the second transistor serves as an output terminal of the transmission processing submodule; and
the positive feedback circuit comprises: a NOR gate and a first transistor, wherein
one input terminal of the NOR gate is connected to the corresponding signal transmission bus, and the other input terminal of the NOR gate is connected to the output terminal of the second inverter; an output terminal of the NOR gate is connected to a gate of the first transistor; and
a source of the first transistor is connected to the first power supply, and a drain of the first transistor is connected to the corresponding signal transmission bus;
the drain of the first transistor serves as an output terminal of the transmission processing submodule.

10. The defect repair circuit according to claim 6, further comprising:
a repair module, connected to the transmission processing module and configured to receive the repair indication signal and replace the address to be accessed by the current operation from the target address to a corresponding redundant address in a case where the repair indication signal is at an active level.

11. The defect repair circuit according to claim 1, further comprising:
a defect information storage module, connected to the matching module and configured to store the defect address and transmit the defect address to the matching module; and
a reset module, connected to the bus and configured to restore the bus to an initial level.

12. The defect repair circuit according to claim 11, wherein the reset module comprises a plurality of third transistors and a plurality of fourth transistors, wherein
a source of each of the plurality of third transistors is connected to a power supply, a drain of each of the plurality of third transistors is connected to one corresponding signal transmission bus, and a gate of each of the plurality of third transistors is configured to receive a first reset signal, wherein the first reset signal is a signal produced when the defect repair circuit receives a new target address; and
a source of each of the plurality of fourth transistors is connected to a power supply, a drain of each of the plurality of fourth transistors is connected to one corresponding signal transmission bus, and a gate of each of the plurality of fourth transistors is configured to receive a second reset signal, wherein the second reset signal is a signal produced when the defect repair circuit is powered on.

13. The defect repair circuit according to claim 6, wherein an active level of the storage area enable signal is a high level; active levels of the matching result signal, the repair indication signal, and the matching signal are all low levels; the first transistor is a positive channel metal oxide semiconductor transistor, and the second transistor is a negative channel metal oxide semiconductor transistor.

14. The defect repair circuit according to claim 1, wherein the matching module further comprises a plurality of redundant rows/columns, the plurality of redundant rows/columns being in a one-to-one correspondence with the plurality of defect addresses; and
the matching module is further configured to direct, according to the matching result signal, the current operation to the redundant row/column corresponding to the defect address matching the target address.

15. A memory, comprising the defect repair circuit according to claim 1.
